(19) United States
(12) Patent Application Publication
(10) Pub. No.: US 2008/0108224 A1
(43) Pub. Date: May 8, 2008

(54) Patterning methods

(76) Inventor: Zhaoning Yu, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/546,663

(22) Filed: Oct. 12, 2006

(51) Int. Cl. H01L 21/302; H01L 21/461

(52) U.S. Cl. 438/745

(57) ABSTRACT

A patterning method includes providing a substrate having an insulator layer established thereon. A silicon layer is established on the insulator layer. A mask is established on at least a portion of the silicon layer. Portions of the silicon layer and the insulator layer are removed to expose portions of the substrate, whereby the silicon layer and insulator layer covered by the mask remain on the substrate. The insulator layer is wet-etched at exposed areas, whereby a height of the insulator layer remains substantially unchanged. The mask and remaining silicon layer are removed.

### BACKGROUND

The present disclosure relates generally to patterning methods.

Nanoscale features (about 100 nm or smaller) are suitable for use in a variety of structures, for example, molecular electronic devices. Various processes and tools (e.g., photolithography, electron-beam lithography, etc.) have been developed for achieving nanoscale features. However, the resolution of these tools (photolithography and electron-beam lithography tools) is, in some instances, limited by the optical diffraction and electron scattering effects. Such limitations may make it difficult to achieve nanoscale features with sizes beyond their resolution limit (e.g., from about 50 to about 100 nm for the current state-of-the-art photolithography tools, or from about 10 to about 30 nm for the current state-of-the-art electron beam lithography tools) or with high aspect ratio.

### BRIEF DESCRIPTION OF THE DRAWINGS

Objects, features and advantages of the present disclosure will become apparent by reference to the following detailed description and drawings, in which like reference numerals correspond to similar, though not necessarily identical components. For the sake of brevity, reference numerals having a previously described function may not necessarily be described in connection with subsequent drawings in which they appear.

FIGS. 1A through 1G together depict a schematic flow diagram depicting an embodiment of the patterning method; and

FIGS. 1A through 1D and 1G together depict a schematic flow diagram depicting an alternate embodiment of the patterning method.

### DETAILED DESCRIPTION

Embodiments of the patterning methods disclosed herein advantageously form nanoscale features or structures having a high-resolution pattern and a high aspect ratio. Throughout embodiments of the method, a height of the structure remains substantially unchanged, while a width of the structure is altered.

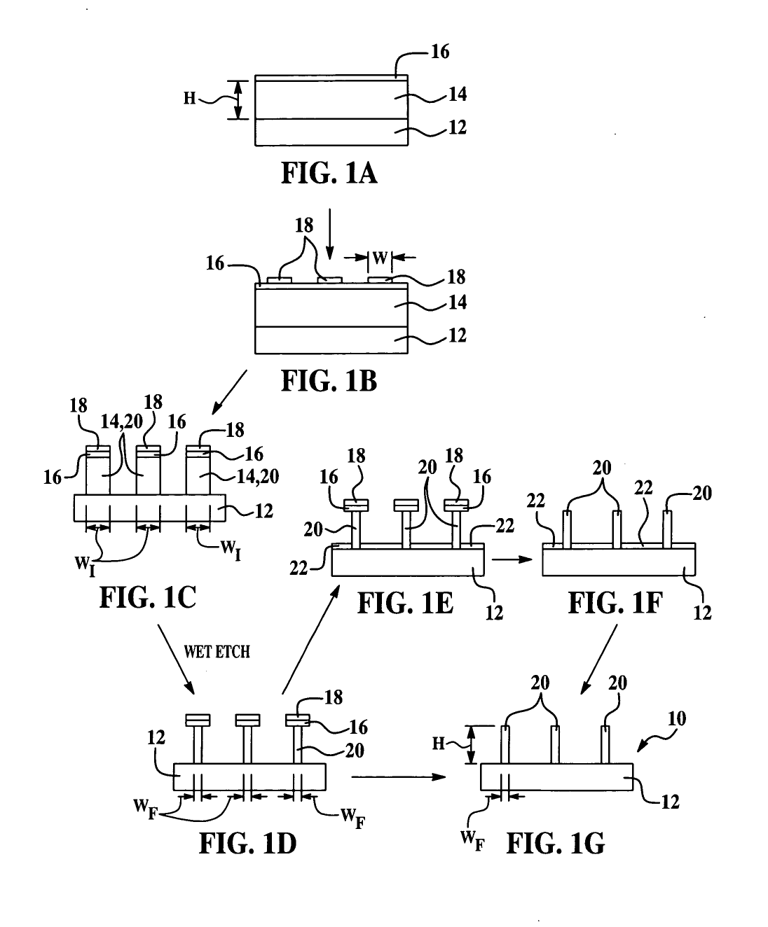

FIGS. 1A, 1B, 1C, 1D, 1E, 1F and 1G together depict a schematic flow diagram of an embodiment of the patterning method disclosed herein. FIGS. 1A, 1B, 1C, 1D and 1G together depict a schematic flow diagram depicting an alternate embodiment of the patterning method disclosed herein. The structure 10 formed via embodiments of the method is depicted in FIG. 1G.

Referring now to FIG. 1A, a substrate 12 has an insulator layer 14 established thereon, and a silicon layer 16 established on the insulator layer 14. Non-limiting examples of suitable substrate 12 materials include silicon wafers, GaAs, quartz, fused silica, GaN, sapphire, and/or other like substrates materials, and/or combinations thereof.

In an embodiment, the substrate 12 is a silicon-on-insulator (SOI) substrate. The pre-purchased or pre-formed SOI substrate includes the substrate 12 (e.g., a silicon wafer), the insulator layer 14 (e.g., silicon dioxide), and the silicon layer 16.

In another embodiment, the insulator layer 14 is established on the substrate 12, and then the silicon layer 16 is established on the insulator layer 14. The layer 14, 16 may be established using any suitable technique. Non-limiting examples of such techniques include thermal growth, evaporation, sputtering, epitaxial growth, low-pressure chemical vapor deposition (LPCVD), plasma enhanced chemical vapor deposition (PECVD), atmospheric pressure chemical vapor deposition (APCVD), or any other suitable chemical or physical vapor deposition techniques.

In the embodiments disclosed herein, silicon dioxide is a suitable material for the insulator layer 14. It is believed that other suitable materials, such as nitrides and oxynitrides, may be used as the insulator layer 14. Generally, the height H of the insulator layer 14 remains substantially unchanged throughout the patterning process; as such, the insulator layer 14 is selected or established to have the desirable height H.

Referring now to FIG. 1B, a mask 18 is established on the silicon layer 16 in any desirable pattern. It is to be understood that the pattern formed by the mask 18 is ultimately transferred to portions of the silicon layer 16 and the insulator layer 14. As such, the mask 18 may be formed having a width W that is desirable for the initial width W_{I} (shown in FIG. 1C) of the nanoscale feature 20.

The mask 18 may be formed of any suitable masking material, including, but not limited to metals (e.g., nickel, chromium, or the like, or combinations thereof), dielectrics, polymers, resist materials, or combinations thereof. Establishing the mask 18 may be accomplished by lithography, lift-off processes, printing (e.g., inkjet or contact printing techniques), radiation beam “writing” processes, scanning probe “writing” processes, or the like, or combinations thereof.

FIG. 1C depicts the removal of portions of the silicon layer 16 and the insulator layer 14 that are not covered by the mask 18. Removal of these layers may be accomplished via reactive ion etching, ion-milling, plasma-enhanced etching, or the like, or combinations thereof. Generally, substantially the entire thickness of these portions of each of the layers 14, 16 is removed so that the portions of the substrate 12 (previously covered by such layers 14, 16) are exposed. It is to be understood that once the removal process is complete, the areas of the layers 14, 16 covered by the mask 18 remain on the substrate 12. This process transfers the pattern of the mask 18 to the silicon layer 16 and the insulator layer 14.

As depicted, the patterned insulator layer 14 forms the nanoscale feature(s) 20, each of which has an initial width W_{I}. As previously described, the initial width W_{I} is the width W of the mask 18. The initial formation of the nanoscale feature(s) 20 leaves at least a portion of the insulator layer 14 directly contacting the silicon layer 16, while other portions are exposed.

After the mask pattern is transferred to the layer 14, 16, the insulator layer 14 (i.e., nanoscale feature(s) 20) is exposed to a wet-etching process. A non-limiting example of such a process is a hydrofluoric (HF) wet-etch. This process substantially etches or trims away exposed areas of the insulator layer 14, thereby leaving a height of the layer/features 14, 20 substantially intact. As such, the initial width W_{I} of the nanoscale feature(s) 20 decreases to a desirable final width W_{F}. It is to be understood that the decrease in width may be controlled, at least in part, by the concentration of the diluted HF and/or by the amount of time the insulator layer 14 is exposed to the wet-etching process. Generally, if the nanoscale feature(s) 20 is/are exposed to a relatively short wet-etch, less of the initial width W_{I} will be reduced than if the nanoscale feature(s) 20 is are exposed to a longer wet-etch. Etching may be accomplished for several seconds to several minutes. The etch time may be calculated by the following equation:

[(initial width−desired final width)/2]/(etch rate)=etch time (1)

As a non-limiting example, the etch rate of thermally grown silicon dioxide in 1:50 diluted HF is about 5 nm/min. In order to reduce an initial width W_{I} of about 50 nm to a final width W_{F} of about 20 nm, the etch time is calculated using equation (1), [(50−20)nm/2]/(5 nm/min)=3 minutes. In another non-limiting example, the initial width W_{I} of the nanoscale feature(s) 20 is about 100 nm, and the final width W_{F} (after wet-etching) of the nanoscale feature(s) 20 is about 10 nm.

As depicted in FIG. 1D, and as previously stated, the silicon layer 16 acts as a barrier to substantially prevent the wet-etch from attacking a top surface of the insulator layer 14. As such, the height H of the insulator layer 14 remains substantially unchanged. It is believed that the silicon layer 16 advantageously protects the directly adjacent areas of the insulator layer 14 during the wet-etch. It is to be understood, however, that areas of the insulator layer 14 that have a surface directly contacting the silicon layer 16 and an exposed surface may be subjected to the wet-etch via the exposed surface. Without being bound to any theory, it is further believed that the silicon layer 16 enables enhanced control over the wet-etch process.

FIGS. 1E through 1G depict one embodiment of the method after the wet-etching process is complete. Generally, this embodiment is utilized when the substrate 12 is formed of silicon. As depicted in FIG. 1E, after the wet-etch process is complete, a protective layer 22 is established on the exposed portions of the substrate 12. This layer 22 advantageously protects the silicon substrate 12 during removal of the silicon layer 16. Non-limiting examples of such a protective layer 22 include nitrides, metals, polymers, resist materials, or combinations thereof. The protective layer 22 may be established via any suitable technique, including, but not limited to evaporation, sputtering, spin-coating, etch-back, or the like, or combinations thereof.

FIG. 1F depicts the removal of the mask 18 and the silicon layer 16, after the establishment of the protective layer 22. Removal of the mask 18 and the silicon layer 16 may occur sequentially or substantially simultaneously. In an embodiment, removal of the mask 18 and silicon layer 16 is accomplished via reactive ion etching or wet chemical etching.

After the mask 18 and silicon layer 16 are removed, this embodiment of the method includes removing the protective layer 22, as shown in FIG. 1G. The protective layer 22 may be removed via chemical wet-etching or plasma-enhanced dry-etching. Removal of the mask 18, silicon layer 16 and protective layer 22 leaves the structure 10 with nanoscale feature(s) 10 having the desirable final width W_{F}.

In another embodiment of the method, after the wet-etching process (as shown in FIG. 1D) is complete, the mask 18 and silicon layer 16 are removed, as shown in FIG. 1G. Generally, this embodiment of the method is suitable when the substrate 12 is a non-silicon material. In this embodiment, since the substrate 12 is a different material than the silicon layer 16, the process for removing the silicon layer 16 will likely not deleteriously affect the substrate 12. As such, a protective layer 22 (as shown in FIGS. 1E and 1F) may be unnecessary in this embodiment. Removal of the mask 18 and silicon layer 16 may be performed as previously described, for example, via reactive ion etching.

As previously described, FIG. 1G depicts the structure 10 with one or more nanoscale features 20 formed thereon. The height H of the features 20 is substantially the same as the initial height of the insulator layer 14 (from which the nanoscale feature(s) 20 are formed). The final width W_{F} of the feature(s) 20 is reduced from an initial width W_{I} of the nanoscale feature(s) 20 (shown FIG. 1C).

While several embodiments have been described in detail, it will be apparent to those skilled in the art that the disclosed embodiments may be modified. Therefore, the foregoing description is to be considered exemplary rather than limiting.

What is claimed is:

1. A patterning method, comprising:
providing a substrate having an insulator layer established thereon, and a silicon layer established on the insulator layer;
establishing a mask on at least a portion of the silicon layer;
removing portions of the silicon layer and the insulator layer to expose portions of the substrate, whereby the silicon layer and insulator layer covered by the mask remain on the substrate;
wet-etching the insulator layer at exposed areas, whereby a height of the insulator layer remains substantially unchanged; and
removing the mask and the remaining silicon layer.

2. The patterning method as defined in claim 1 wherein the substrate is a silicon-on-insulator substrate including:
a silicon wafer;
the insulator layer established on the silicon wafer; and
the silicon layer established on the insulator layer.

3. The patterning method as defined in claim 2 wherein the insulator layer is silicon dioxide.

4. The patterning method as defined in claim 2 wherein prior to removing the mask and the remaining silicon layer, the method further comprises establishing a protective layer on the exposed portions of the substrate, and wherein subsequent to removing the mask and the remaining silicon layer, the method further comprises removing the protective layer.

5. The patterning method as defined in claim 4 wherein the protective layer is selected from nitride, metals, polymers, resist materials, and combinations thereof.

6. The patterning method as defined in claim 4 wherein establishing the protective layer is accomplished by evaporation, sputtering, spin-coating, etch-back or combinations thereof, and wherein removing the protective layer is accomplished by wet-chemical etching, plasma-enhanced dry-etching or combinations thereof.

7. The patterning method as defined in claim 1 wherein wet-etching is accomplished via HF wet-etching.

8. The patterning method as defined in claim 1 wherein wet-etching decreases a width of the insulator layer.

9. The patterning method as defined in claim 8 wherein wet-etching is accomplished for a predetermined time, thereby enabling control of the width of the insulator layer.

10. The patterning method as defined in claim 8 wherein an initial width of the insulator layer is about 100 nm, and wherein the decreased width of the insulator layer is about 10 nm.

11. The patterning method as defined in claim 1 wherein establishing the mask is accomplished via lithography, lift-off processes, printing, a beam of radiation, a scanning probe, or combinations thereof.

12. The patterning method as defined in claim 11 wherein the mask is selected from metals, polymers, resist materials, and combinations thereof.

13. The patterning method as defined in claim 1 wherein removing the portions of the silicon layer and the insulator layer is accomplished by reactive ion etching.

14. The patterning method as defined in claim 1 wherein the substrate is selected from silicon, GaAs, quartz, fused silica, GaN, sapphire, and combinations thereof.

15. The patterning method as defined in claim 1 wherein removing portions of the silicon layer and the insulator layer transfers a pattern formed by the mask to the silicon layer and the insulator layer.

16. A structure, comprising:
a substrate; and
at least one insulating structure established on the substrate, the insulating structure having had a silicon layer established thereon during an HF wet-etching process and subsequently removed, the silicon layer enabling a height of the insulating structure to remain substantially unchanged during the HF wet-etching process.

17. The structure as defined in claim 16 wherein the substrate is a silicon wafer, wherein the insulating structure is formed of silicon dioxide, and wherein the structure further comprises a protective layer established on the substrate during the HF wet-etching process.

18. A patterning method, comprising:
establishing an insulator layer on a substrate, the insulator layer having a predetermined height;
establishing a silicon layer on the insulator layer;
establishing a mask on at least a portion of the silicon layer, thereby forming a pattern;
removing portions of the silicon layer and the insulator layer not covered by the mask, thereby exposing portions of the substrate and transferring the pattern to the silicon layer and the insulator layer;
HF wet-etching the insulator layer at exposed areas, whereby the predetermined height of the insulator layer remains substantially unchanged, and a width of the insulator layer decreases;
removing the mask; and
removing the remaining silicon layer, thereby exposing the etched insulator layer.

19. The patterning method as defined in claim 18 wherein the substrate is silicon, wherein prior to removing the remaining silicon layer, the method further comprises establishing a protective layer on the exposed portions of the substrate, and wherein subsequent to removing the remaining silicon layer, the method further comprises removing the protective layer.

20. The patterning method as defined in claim 18 wherein HF wet-etching is accomplished for a predetermined time, thereby enabling control of the width of the insulator layer.
